(19) United States
(12) Patent Application Publication
(10) Pub. No.: US 2025/0157713 A1
(43) Pub. Date: May 15, 2025

(54) Inductor apparatus having dynamic inductance adjusting mechanism

(71) Applicant: REALTEK SEMICONDUCTOR CORPORATION, Hsinchu (TW)

(72) Inventor: CHENG-WEI LUO, Hsinchu (TW)

(21) Appl. No.: 18/939,586

(22) Filed: Nov. 7, 2024

(30) Foreign Application Priority Data
Nov. 9, 2023 (TW) 112143247

(51) Int. Cl. H01F 21/12; H03B 5/12

(52) U.S. Cl. CPC H01F 21/12; H03B 5/12

(57) ABSTRACT

The present disclosure discloses an inductor apparatus having dynamic inductance adjusting mechanism that includes a primary coil, a secondary coil and a pair of switch circuits. The primary coil includes a primary coil main body and a pair of primary terminals that electrically coupled an external circuit. The secondary coil has a secondary coil main body electrically coupled to the primary coil main body and a pair of secondary terminals. A first one of the primary coil main body and the secondary coil main body surrounds a second one of the primary coil main body and the secondary coil main body. The switch circuits control the pair of secondary terminals to be floating in a first mode and controls the pair of secondary terminals to be electrically coupled to the pair of primary terminals in a second mode.

### BACKGROUND OF THE INVENTION

### 1. Field of the Invention

The present disclosure relates to an inductor apparatus having dynamic inductance adjusting mechanism.

### 2. Description of Related Art

An inductor is an electronic component that generates an electromotive force against a variation of a current flowing therethrough. In current integrated circuit design, circuits operating in different frequency bands are integrated in a single chip. In order to satisfy different requirements of these circuits, different inductors are disposed to match the needs of these circuits. The area of the circuits is thus increased.

### SUMMARY OF THE INVENTION

In consideration of the problem of the prior art, an object of the present disclosure is to provide an inductor apparatus having dynamic inductance adjusting mechanism.

The present invention discloses an inductor apparatus having dynamic inductance adjusting mechanism that includes a primary coil, a secondary coil and a pair of switch circuits. The primary coil includes a primary coil main body and a pair of primary terminals that electrically coupled to an external circuit. The secondary coil includes a secondary coil main body electrically coupled to the primary coil main body and a pair of secondary terminals, wherein a first one of the primary coil main body and the secondary coil main body surrounds a second one of the primary coil main body and the secondary coil main body. The pair of switch circuits are configured to control the pair of secondary terminals to be floating in a first mode and control the pair of secondary terminals to be electrically coupled to the pair of primary terminals in a second mode.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1A and FIG. 1B each illustrates a diagram of an inductor apparatus having dynamic inductance adjusting mechanism according to an embodiment of the present invention.

FIG. 2 illustrates a diagram of a relation of an operation frequency and an inductance of the inductor apparatus when the switch circuits operate in the first mode and the second mode according to an embodiment of the present invention.

FIG. 3 illustrates an inductor apparatus having dynamic inductance adjusting mechanism according to an embodiment of the present invention.

FIG. 4 illustrates a diagram of a relation of an operation frequency and an inductance of the inductor apparatus when the switch circuits operate in the first mode and the second mode according to an embodiment of the present invention.

FIG. 5A to FIG. 5C each illustrates an inductor apparatus having dynamic inductance adjusting mechanism according to an embodiment of the present invention.

### DETAILED DESCRIPTION OF THE PREFERRED EMBODIMENTS

An aspect of the present invention is to provide an inductor apparatus having dynamic inductance adjusting mechanism to allow a secondary coil to selectively be electrically isolated from or electrically coupled to a primary coil according to the operation of switch circuits, such that an equivalent coil width of the inductor apparatus is adjusted to further adjust an equivalent coil inductance thereof.

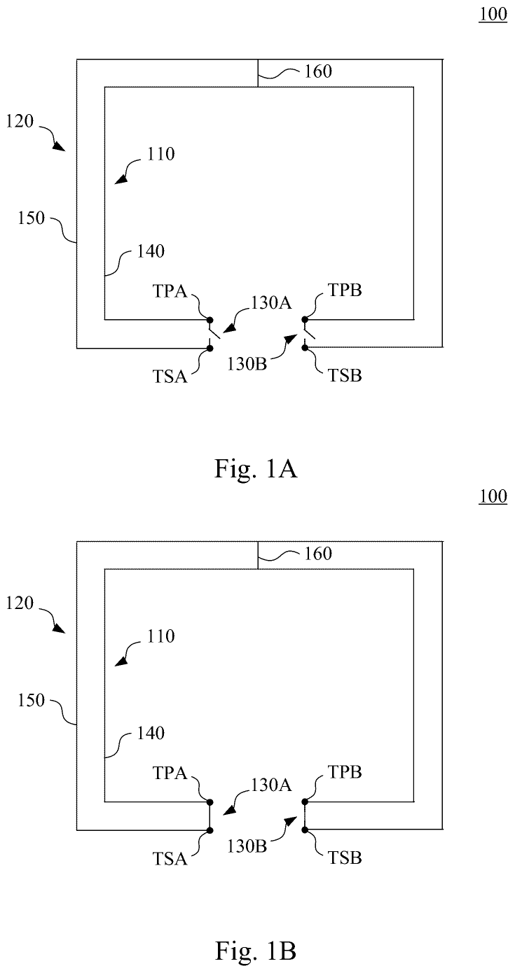

Reference is now made to FIG. 1A and FIG. 1B at the same time. FIG. 1A and FIG. 1B each illustrates a diagram of an inductor apparatus 100 having dynamic inductance adjusting mechanism according to an embodiment of the present invention.

The inductor apparatus 100 includes a primary coil 110, a secondary coil 120 and a pair of switch circuits 130A and 130B.

The primary coil 110 includes a primary coil main body 140 and a pair of primary terminals TPA and TPB. The primary terminals TPA and TPB are electrically coupled to an external circuit (not illustrated). In an embodiment, the inductor apparatus 100 is disposed in a voltage control oscillator (not illustrated) and is electrically coupled to other electronic components in the voltage control oscillator such that the voltage control oscillator generates an oscillating activity according to a control voltage. However, the present invention is not limited thereto.

In an embodiment, the secondary coil 120 and the primary coil 110 are disposed at the same circuit layer. The secondary coil 120 has a secondary coil main body 150 electrically coupled to the primary coil main body 140 and a pair of secondary terminals TSA and TSB. In the embodiment in FIG. 1A and FIG. 1B, the secondary coil main body 150 and the primary coil main body 140 are electrically coupled together through a coupling structure 160. In an embodiment, the coupling structure 160 serves as a central tap of the primary coil 110 and the secondary coil 120.

A first one of the primary coil main body 140 and the secondary coil main body 150 surrounds a second one of the primary coil main body 140 and the secondary coil main body 150. In the embodiment in FIG. 1A and FIG. 1B, the secondary coil main body 150 surrounds the primary coil main body 140. It is appreciated that in the embodiment in FIG. 1A and FIG. 1B, each of the primary coil main body 140 and the secondary coil main body 150 is a coil of a single turn. However, the coil in the present invention is not limited to a certain number of turns. When the secondary coil main body 150 is a coil with a plurality of turns, the coil structure with the plurality of turns are disposed to surround the primary coil main body 140.

The switch circuits 130A and 130B are configured to control the pair of the secondary terminals TSA and TSB to be floating in a first mode illustrated in FIG. 1A and control the pair of the secondary terminals TSA and TSB to be electrically coupled to the pair of primary terminals TPA and TPB in a second mode illustrated in FIG. 1B. In an embodiment, the switch circuits 130A and 130B operate in either the first mode or the second mode according to the control of the different states (e.g., a logic high state and a logic low state) of a control signal CS.

A first equivalent coil width that the inductor apparatus 100 has when the pair of switch circuits 130A and 130B operate in the second mode is larger than a second equivalent coil width that the inductor apparatus 100 has when the pair of switch circuits 130A and 130B operate in the first mode, such that a first equivalent coil inductance that the inductor apparatus 100 has when the pair of switch circuits 130A and 130B operates in the second mode is lower than a second equivalent coil inductance that the inductor apparatus 100 has when the pair of switch circuits 130A and 130B operates in the first mode.

More specifically, when the switch circuits 130A and 130B operate in the first mode, the equivalent coil width of the inductor apparatus 100 is the width of the primary coil main body 140 of the primary coil 110. When the switch circuits 130A and 130B operate in the second mode, the equivalent coil width of the inductor apparatus 100 is a sum of the width of the primary coil main body 140 of the primary coil 110 and the width of the secondary coil main body 150 of the secondary coil 120.

Since the equivalent coil inductance of the inductor apparatus 100 is smaller when the equivalent coil width thereof is larger, the equivalent coil inductance that the inductor apparatus 100 has when the pair of switch circuits 130A and 130B operates in the second mode is lower than the equivalent coil inductance that the inductor apparatus 100 has when the pair of switch circuits 130A and 130B operates in the first mode. The calculation method of the equivalent coil width and the equivalent coil inductance can be referred to the thesis “Simple Accurate Expressions for Planar Spiral Inductances” in IEEE JOURNAL OF SOLID-STATE CIRCUITS, VOL. 34, NO. 10, October 1999 and is not described herein

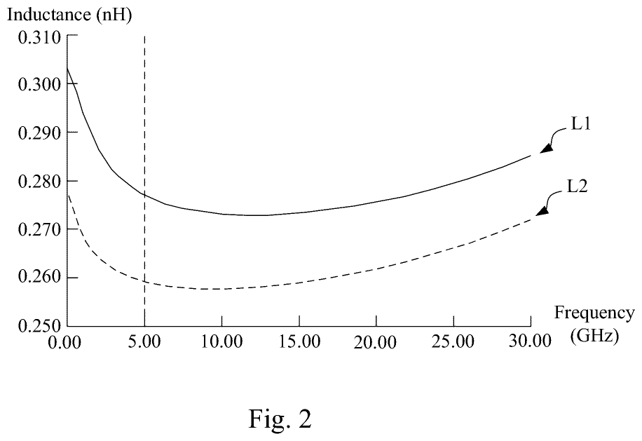

Reference is now made to FIG. 2. FIG. 2 illustrates a diagram of a relation of an operation frequency and an inductance of the inductor apparatus 100 when the switch circuits 130A and 130B operate in the first mode and the second mode according to an embodiment of the present invention.

In FIG. 2, the X-axis represents the frequency in the unit of GHz, and the Y-axis represents the inductance in the unit of nH. A line section L1 illustrated in a solid line corresponds to the performance of the inductor apparatus 100 when the switch circuits 130A and 130B operate in the first mode. A line section L2 illustrated in a dashed line corresponds to the performance of the inductor apparatus 100 when the switch circuits 130A and 130B operate in the second mode.

As illustrated in FIG. 2, take the operation frequency of 5 GHz as an example, the inductance (0.2771 nH) that the inductor apparatus 100 has when the switch circuits 130A and 130B operate in the first mode is larger than the inductance (0.2593 nH) that the inductor apparatus 100 has when the switch circuits 130A and 130B operate in the second mode.

As a result, the inductor apparatus of the present invention allows the secondary coil to selectively be electrically isolated from or electrically coupled to the primary coil according to the operation of switch circuits, such that the equivalent coil width of the inductor apparatus is adjusted to further adjust the equivalent coil inductance thereof. In an embodiment, when the inductor apparatus 100 is disposed in the voltage control oscillator as described above, the control signal CS can be generated by the voltage control oscillator according to the required oscillating frequency to control the operation mode of the switch circuits 130A and 130B to further adjust the oscillating frequency to a required frequency value based on the equivalent coil inductance corresponding to the operation mode.

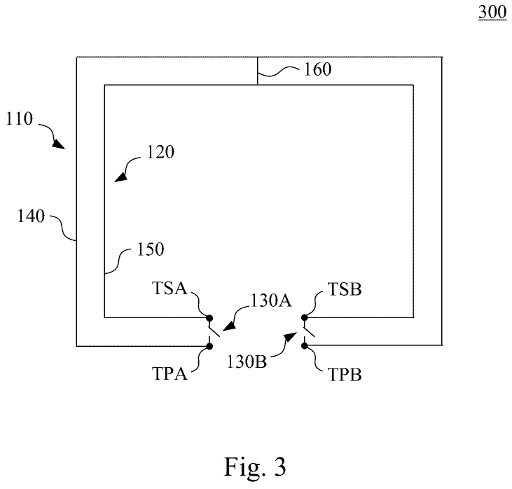

Reference is now made to FIG. 3. FIG. 3 illustrates an inductor apparatus 300 having dynamic inductance adjusting mechanism according to an embodiment of the present invention.

Similar to the inductor apparatus 100, the inductor apparatus 300 includes the primary coil 110, the secondary coil 120 and the switch circuits 130A and 130B. However, in the present embodiment, the secondary coil main body 150 of the secondary coil 120 is surrounded by the primary coil main body 140 of the primary coil 110.

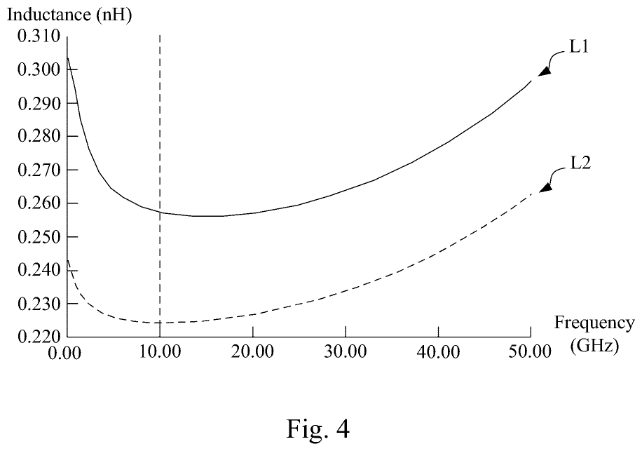

Reference is now made to FIG. 4. FIG. 4 illustrates a diagram of a relation of an operation frequency and an inductance of the inductor apparatus 300 when the switch circuits 130A and 130B operate in the first mode and the second mode according to an embodiment of the present invention.

In FIG. 4, the X-axis represents the frequency in the unit of GHz, and the Y-axis represents the inductance in the unit of nH. A line section L1 illustrated in a solid line corresponds to the performance of the inductor apparatus 300 when the switch circuits 130A and 130B operate in the first mode. A line section L2 illustrated in a dashed line corresponds to the performance of the inductor apparatus 300 when the switch circuits 130A and 130B operate in the second mode.

As illustrated in FIG. 4, take the operation frequency of 10 GHz as an example, the inductance (0.2571 nH) that the inductor apparatus 100 has when the switch circuits 130A and 130B operate in the first mode is larger than the inductance (0.2242 nH) that the inductor apparatus 100 has when the switch circuits 130A and 130B operate in the second mode.

In the embodiments described above, the condition that the number of the secondary coil is one is used as an example. In other embodiments, the number of the secondary coil can be more than one and these secondary coils can be disposed relative to the primary coil based on different methods.

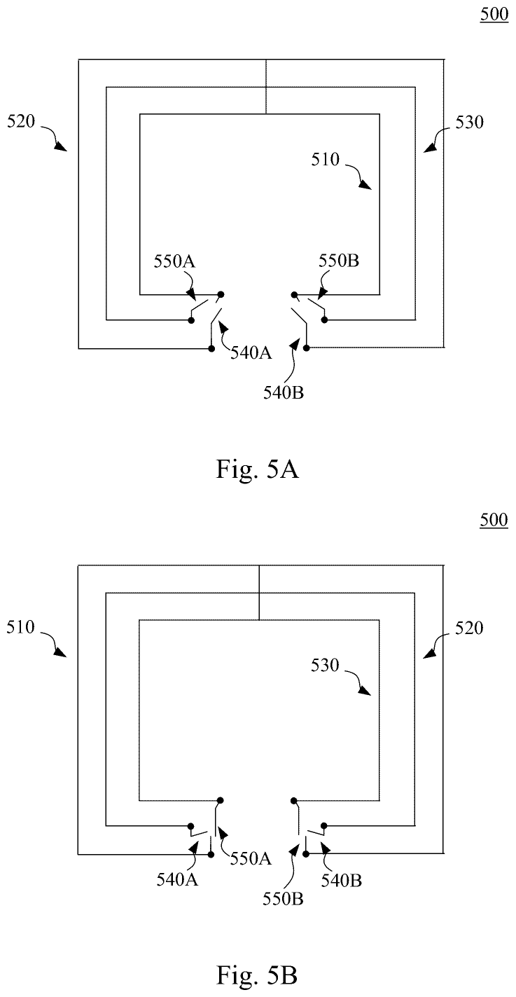

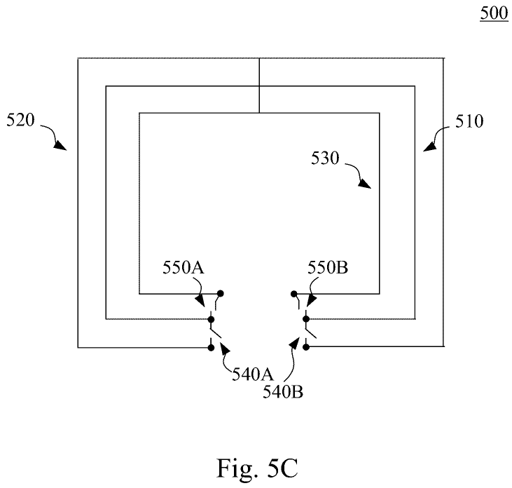

Reference is now made to FIG. 5A to FIG. 5C. FIG. 5A to FIG. 5C each illustrates an inductor apparatus 500 having dynamic inductance adjusting mechanism according to an embodiment of the present invention.

The inductor apparatus 500 includes a primary coil 510, a secondary coil 520, a secondary coil 530, a pair of switch circuits 540A and 540B and a pair of switch circuits 550A and 550B. The switch circuits 540A and 540B correspond to the secondary coil 520 and operate in either the first mode or the second mode. The switch circuits 550A and 550B correspond to the secondary coil 530 and operate in either the first mode or the second mode.

In the embodiment of FIG. 5A, the secondary coil main body (not labeled) of each of the secondary coils 520 and 530 in turn surrounds the primary coil main body (not labeled) of the primary coil 510 from one of the secondary coils having the largest size to one of the secondary coils having the smallest size. In the embodiment of FIG. 5B, the secondary coil main body (not labeled) of each of the secondary coils 520 and 530 in turn are surrounded by the primary coil main body (not labeled) of the primary coil 510 from one of the secondary coils having the largest size to one of the secondary coils having the smallest size. In the embodiment of FIG. 5C, the secondary coil main body (not labeled) of each of a first part of the secondary coils 520 and 530 (e.g., the secondary coil 520) in turn surrounds the primary coil main body (not labeled) of the primary coil 510 from one of the secondary coils having the largest size to one of the secondary coils having the smallest size. the secondary coil main body (not labeled) of each of a second part of the secondary coils 520 and 530 (e.g., the secondary coil 530) in turn is surrounded by the primary coil main body (not labeled) of the primary coil 510 from one of the secondary coils having the largest size to one of the secondary coils having the smallest size.

In the embodiments described above, the condition that the number of the secondary coils is two is used as an example. In other embodiments, the number of the secondary coils can be more than two and the number of the secondary coils surrounding the primary coil and the number of the secondary coils surrounded by the primary coil can be configured according to practical requirements. When the number of the secondary coils is larger, the number of the values of the equivalent coil inductance of the inductor apparatus that can be adjusted can be larger as well.

It is appreciated that the embodiments described above are merely an example. In other embodiments, it is appreciated that many modifications and changes may be made by those of ordinary skill in the art without departing, from the spirit of the invention.

In summary, the inductor apparatus having dynamic inductance adjusting mechanism allows a secondary coil to selectively be electrically isolated from or electrically coupled to a primary coil according to the operation of switch circuits, such that an equivalent coil width of the inductor apparatus is adjusted to further adjust an equivalent coil inductance thereof.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. An inductor apparatus having dynamic inductance adjusting mechanism, comprising:
a primary coil comprising a primary coil main body and a pair of primary terminals that electrically coupled to an external circuit;
a secondary coil comprising a secondary coil main body electrically coupled to the primary coil main body and a pair of secondary terminals, wherein a first one of the primary coil main body and the secondary coil main body surrounds a second one of the primary coil main body and the secondary coil main body; and
a pair of switch circuits configured to control the pair of secondary terminals to be floating in a first mode and control the pair of secondary terminals to be electrically coupled to the pair of primary terminals in a second mode.

2. The inductor apparatus of claim 1, wherein the secondary coil main body surrounds the primary coil main body.

3. The inductor apparatus of claim 1, wherein the secondary coil main body is surrounded by the primary coil main body.

4. The inductor apparatus of claim 1, wherein the inductor apparatus comprises N secondary coils with different sizes and N pairs of switch circuits corresponding to the N secondary coils that operate in either the first mode or the second mode.

5. The inductor apparatus of claim 4, wherein the secondary coil main body of each of the N secondary coils in turn surrounds the primary coil main body from one of the N secondary coils having a largest size to one of the N secondary coils having a smallest size.

6. The inductor apparatus of claim 4, wherein the secondary coil main body of each of the N secondary coils is in turn surrounded by the primary coil main body from one of the N secondary coils having a largest size to one of the N secondary coils having a smallest size.

7. The inductor apparatus of claim 4, wherein the secondary coil main body of each of a first part of the N secondary coils in turn surrounds the primary coil main body from one of the first part of the N secondary coils having a largest size to one of the first part of the N secondary coils having a smallest size, and the secondary coil main body of each of a second part of the N secondary coils in turn are surrounded by the primary coil main body from one of the second part of the N secondary coils having a largest size to one of the second part of the N secondary coils having a smallest size.

8. The inductor apparatus of claim 1, wherein a first equivalent coil width that the inductor apparatus has when the pair of switch circuits operate in the second mode is larger than a second equivalent coil width that the inductor apparatus has when the pair of switch circuits operate in the first mode, such that a first equivalent coil inductance that the inductor apparatus has when the pair of switch circuits operates in the second mode is lower than a second equivalent coil inductance that the inductor apparatus has when the pair of switch circuits operates in the first mode.

9. The inductor apparatus of claim 1, wherein the primary coil and the secondary coil are disposed at a same circuit layer.

10. The inductor apparatus of claim 1, wherein the inductor apparatus is disposed in a voltage control oscillator (VCO) to control the pair of switch circuits according to a control signal generated by the voltage control oscillator according to a required oscillating frequency.
